(19) United States
(12) Patent Application Publication
(10) Pub. No.: US 2005/0179045 A1
(43) Pub. Date: Aug. 18, 2005

(54) Nitride semiconductor light emitting diode having improved ohmic contact structure and fabrication method thereof

(76) Inventors: Yung Ho Ryu, Seoul (KR); Kee Jeong Yang, Seoul (KR); Bang Won Oh, Sungnam (KR); Jin Sub Park, Suwon (KR)

Correspondence Address: LOWE HAUPTMAN GILMAN AND BERNER, LLP, 1700 DIAGONAL ROAD, SUITE 300 /310, ALEXANDRIA, VA, 22314, US

(21) Appl. No.: 10/857,932

(22) Filed: Jun. 2, 2004

(30) Foreign Application Priority Data
Feb. 13, 2004 (KR) 2004-9731

(51) Int. Cl. H01L 29/22; H01L 33/00

(52) U.S. Cl. 257/94

(57) ABSTRACT

Disclosed is a nitride semiconductor LED and a fabrication method thereof. An n-doped semiconductor layer, an active layer, a p-doped semiconductor layer and a p⁺-doped semiconductor layer are formed in their order on a substrate. A resultant semiconductor structure is mesa-etched to expose a partial area of the n-doped semiconductor layer. The p⁺-doped semiconductor layer and the exposed area of the n-doped semiconductor layer are n-doped at a high concentration to form first and second n⁺-doped regions, respectively. P- and n-electrodes are formed on the first and second n⁺-doped regions, respectively. Then, reverse bias is created to improve an ohmic contact structure between a semiconductor layer and a metal electrode thereby lowering drive voltage while raising overvoltage resistance and luminance.

### CLAIM OF PRIORITY

This application claims the benefit of Korean Patent Application No. 2004-9731 filed on Feb. 13, 2004, in the Korean Intellectual Property Office, the disclosure of which is incorporated herein by reference.

### BACKGROUND OF THE INVENTION

1. Field of the Invention

The present invention relates to a nitride semiconductor Light Emitting Diode (LED), and more particularly, to a nitride semiconductor LED and a fabrication method thereof capable of creating reverse bias to improve an ohmic contact structure between a semiconductor layer and a metal electrode thereby lowering drive voltage while raising overvoltage resistance and luminance.

2. Description of the Related Art

In general, nitride semiconductors are used in LEDs for generating blue or green wavelength light. Representative examples of semiconductor may be expressed by an equation of AlₓIn_{y}Ga_{(1-x-y)}N, wherein 0≦x≦1, 0≦y≦1 and 0≦x+y≦1.

LEDs for generating green light are produced by using GaN semiconductors having a wide band gap of about 3.4 eV. A nitride semiconductor of for example GaN has a wide band gap, which acts as a problem in the formation of electrodes and ohmic contact structures. In more detail, there are problems in that contact resistance raised in a p-electrode region resultantly increases the drive voltage and the heat generation of a device. While various schemes may be proposed as means for forming the ohmic contact structures, those regions defining the ohmic contact structures also function as major light emitting surfaces, followed by critical requirements that light generated from an active layer be transmitted through the ohmic contact structures, so as to extremely limit the range of actually adoptable means.

As a conventional technique satisfying such requirements, there is proposed U.S. Pat. No. 5,563,422, which is entitled “Gallium Nitride-Based III-V Group Compound Semiconductor Device and Method of Producing the Same” and assigned to Nichia Chemical Industries, Ltd. This document proposes a transparent electrode layer using a Ni/Au double layer, and a structure of a nitride semiconductor LED disclosed in this document is shown in FIG. 1.

As shown in FIG. 1, a conventional nitride semiconductor LED 10 includes an n-doped GaN cladding layer 13, a GaN/InGaN active layer 15 of a Multiple Quantum Well (MQW) structure and a p-doped GaN cladding layer 17 formed in their order on a sapphire (Al₂O₃) substrate 11, in which the p-doped GaN cladding layer 17 and the GaN/InGaN active layer 15 are removed in part to partially expose the top surface of the n-dope GaN cladding layer 13. The nitride semiconductor LED 10 also includes an n-electrode 19a formed on the n-doped GaN cladding layer 13 and an ohmic contact structure that consists of a transparent electrode 18 of Ni/Au formed on the p-doped GaN cladding layer 17 and a p-bonding electrode 19b formed on the transparent electrode 18. The transparent electrode 18 is provided to improve contact resistance while ensuring transparency, and may be obtained via deposition of a Ni/Au double layer and subsequent heat treatment.

However, according to the afore-described technique, the transparent electrode attached on the p-doped semiconductor layer, ohmic contact properties become relatively poor thereby to increase drive voltage. It is also difficult to improve luminance since the transparent electrode to be attached on the p-doped semiconductor layer is limited to relatively low transparency metal such as Ni/Au owing to weak bonding force. Furthermore, the n-doped GaN cladding layer shows relatively bad overvoltage resistance when bonded with the n-electrode.

### SUMMARY OF THE INVENTION

The present invention has been made to solve the foregoing problems of the prior art and it is therefore an object of the present invention to provide a nitride semiconductor LED capable of creating reverse bias to improve an ohmic contact structure between a semiconductor layer and a metal electrode thereby lowering drive voltage while raising overvoltage resistance and luminance.

It is another object of the invention to provide a fabrication method capable of producing the above nitride semiconductor LED.

According to an aspect of the invention for realizing the object, there is provided a nitride semiconductor Light Emitting Diode (LED) comprising: an n-doped semiconductor layer formed on a substrate; an active layer formed on the n-doped semiconductor layer to expose a partial area of the n-doped semiconductor layer; a p-doped semiconductor layer formed on the active layer; a p⁺-doped semiconductor layer formed on the p-doped semiconductor layer; first and second n³⁰ -doped regions of a high n-dopant concentration formed on the p⁺-doped semiconductor layer and the exposed area of the n-doped semiconductor layer, respectively; and p- and n-electrodes formed on the first and second n⁺-doped regions, respectively.

According to another aspect of the invention for realizing the object, there is provided a fabrication method of nitride semiconductor Light Emitting Diodes (LEDs), the method comprising the following steps of: forming an n-doped semiconductor layer, an active layer, a p-doped semiconductor layer and a p⁺-doped semiconductor layer in their order on a substrate; mesa-etching a resultant semiconductor structure to expose a partial area of the n-doped semiconductor layer; n-doping the p⁺-doped semiconductor layer and the exposed area of the n-doped semiconductor layer at a high concentration to form first and second n⁺-doped regions, respectively; and forming p- and n-electrodes on the first and second n⁺-doped regions, respectively.

In the fabrication method of nitride semiconductor LEDs of the invention, the n-doping step comprises: forming a silicon dioxide (SiO₂) layer on the mesa-etched semiconductor structure; selectively etching the silicon dioxide layer to expose at least a portion of the p⁺-doped semiconductor layer and at least a portion of the exposed area of the n-doped semiconductor layer; and ion-implanting n-dopants through the etched regions of the silicon dioxide layer into the p⁺-doped semiconductor layer and the exposed area of the n-doped semiconductor layer.

According to still another aspect of the invention for realizing the object, there is provided a fabrication method of nitride semiconductor Light Emitting Diodes (LEDs), the method comprising the following steps of: forming a first n-doped semiconductor layer, an active layer, a p-doped semiconductor layer, a p⁺-doped semiconductor layer and a second n-doped semiconductor layer in their order on a substrate; mesa-etching a resultant semiconductor structure to expose a partial area of the first n-doped semiconductor layer; n-doping the second n-doped semiconductor layer to form itself into a first n⁺-doped region and the exposed area of the first n-doped semiconductor layer to form a second n⁺-doped region therein; and forming p- and n-electrodes on the first and second n⁺-doped regions, respectively.

In the fabrication method of nitride semiconductor LEDs of the invention, the n-doping step comprises: forming a silicon dioxide (SiO₂) layer on the mesa-etched semiconductor structure; selectively etching the silicon dioxide layer to expose at least a portion of the second n-doped semiconductor layer and at least a portion of the exposed area of the n-doped semiconductor layer; and ion-implanting n-dopants through the etched regions of the silicon dioxide layer into the second n-doped semiconductor layer and the exposed area of the first n-doped semiconductor layer.

### BRIEF DESCRIPTION OF THE DRAWINGS

FIG. 1 is a side sectional view illustrating a nitride semiconductor LED of the prior art;

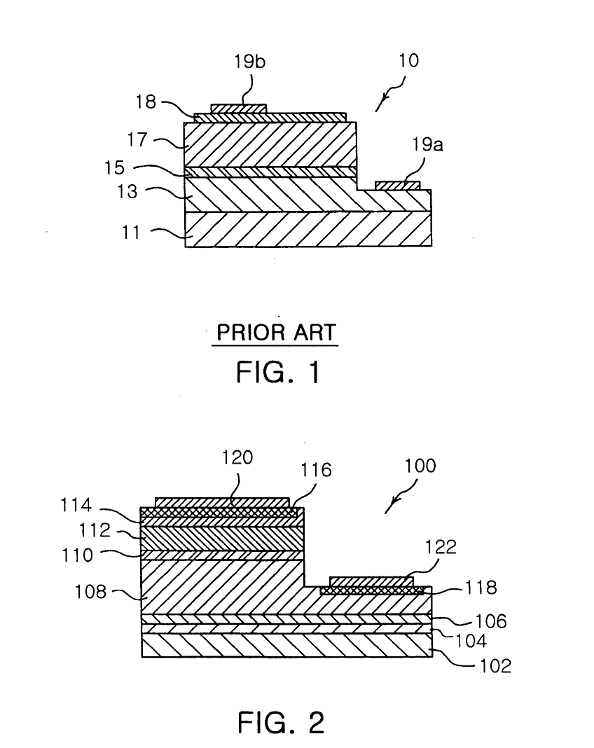

FIG. 2 is a side sectional view illustrating a nitride semiconductor LED of the invention;

FIGS. 3 to 6 are stepwise sectional views illustrating a first embodiment of a fabrication method of nitride semiconductors of the invention; and

FIGS. 7 to 11 are stepwise sectional views illustrating a second embodiment of a fabrication method of nitride semiconductors of the invention.

### DETAILED DESCRIPTION OF THE PREFERRED EMBODIMENT

Hereinafter the above and other objects, features and other advantages of the present invention will be described in detail in conjunction with the accompanying drawings.

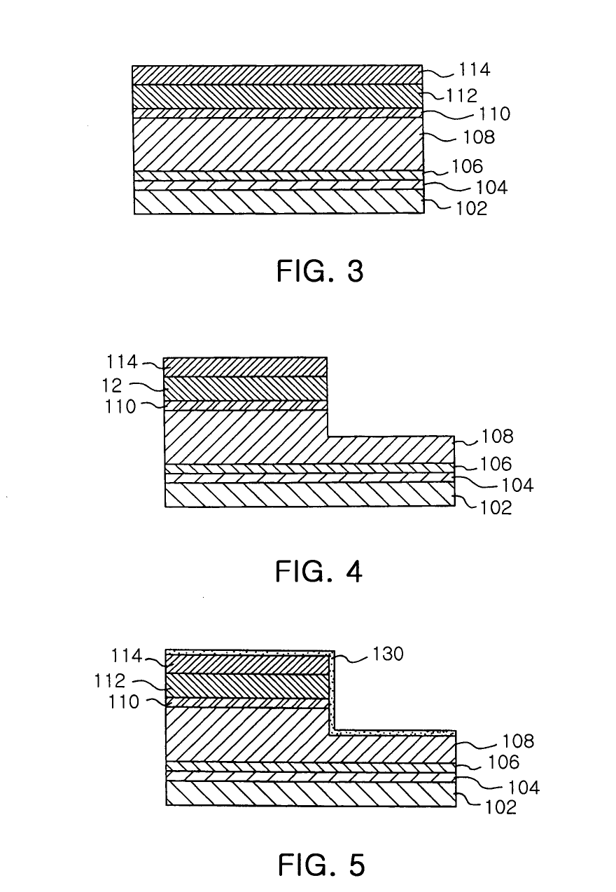

FIG. 2 is a side sectional view illustrating a nitride semiconductor LED of the invention.

Referring to FIG. 2, a nitride semiconductor LED 100 of the invention includes a buffer layer 104, a plurality of semiconductor layers 104 to 114, first and second high concentration n-doped or n⁺-doped regions 116 and 118 and p- and n-transparent metal layers 120 and 122 which are formed in their order on a sapphire (Al₂O₃) substrate 102.

The buffer layer 104 formed on the sapphire substrate 102 decreases the stress induced between the sapphire substrate 102 and an overlying nitride semiconductor layer to enable epitaxial growth therebetween since the nitride semiconductor layer has a poor wettability with the sapphire substrate 102 owing to significant lattice constant mismatch.

An undoped GaN layer 106 is formed on the buffer layer 104, and an n-doped cladding or semiconductor layer 108 is formed on the undoped GaN layer 106. An active layer 110 is formed on the n-doped semiconductor layer 108 to partially expose the n-doped semiconductor layer 108. Hereinafter a partial area of the n-doped semiconductor layer 108 covered with the active layer 110 will be referred to as “first area”,and another area of the n-doped semiconductor layer 108 without the active layer 110 will be referred to as “second area.”

The active layer 110 for generating light is constituted of a Multiple Quantum Well (MQW) structure formed by growing wells typically of InGaN and barrier layers of (Al)GaN. Blue LEDs use an MQW structure of for example InGaN/GaN, and ultraviolet (UV) LEDs use MQW structures of for example GaN/AlGaN, InAlGaN/InAlGaN or InGaN/AlGaN. As for the efficiency improvement of active layers as above, the internal quantum efficiency ηᵢ is improved by adjusting light wavelength through variation in the content of In or Al or by changing the quantum well depth, the number or thickness of active layers.

A p-doped cladding layer is formed on the active layer 110. The p-doped cladding layer includes a p-doped semiconductor layer 112 formed on the active layer 110 and a high concentration p-doped or p⁺-doped semiconductor layer 114 formed on the p-doped semiconductor layer 112. The p⁺-doped semiconductor layer has a thickness of about 10 Å to 1 μm.

Herein, the first n⁺-GaN layer or n⁺-doped region 116 containing high concentration n dopants is formed in an upper portion of the p-doped semiconductor layer 114, and the second n⁺-GaN layer or n⁺-doped region 118 containing high concentration n dopants is formed in an upper portion of the exposed second area of the n-doped semiconductor layer 108.

N dopants implanted into the first and second n⁺-doped regions 116 and 118 are selected from the group consisting of C, Si, Ge, Sn, N, P, As and Sb, and doped preferably at a concentration of 1E18 to 1E 20 atoms/cm³ via ion implantation. The first and second n⁺-doped regions 116 and 118 have a thickness of about 10 Å to 1 μm, and preferably, of about 100 to 1000 Å.

The first n⁺-doped region 116 formed on the p⁺-doped semiconductor layer 114 can create reverse bias to form a tunneling junction thereby ensuring an excellent ohmic contact structure as well as decreasing drive voltage.

The second n⁺-doped region 118 formed in the exposed second area of the n-doped nitride layer 108 can improve overvoltage resistance, and has ohmic contact property and metal bonding force superior to those of the n-doped semiconductor layer 108 of N-GaN.

As the first and second n⁺-doped regions 116 and 118 improve the ohmic contact, each of the p-transparent metal layer 120 and the n-transparent metal layer 122 functioning as transparent electrodes can be readily made from one selected from the group consisting of Indium-Tin Oxide (ITO), Cadmium-Tin Oxide (CTO) and Titanium Tungsten Nitride (TiWN). The transparent electrodes of the invention can improve the luminance of the nitride semiconductor LED 100 since they have light transparency superior to that of conventional transparent electrodes of for example Ni/Au, in which for example ITO has a light transparency of about 90 to 98% but Ni/Au has a light transparency of about 65 to 80%.

As not shown in FIG. 2, p- and n-bonding electrodes also may be formed on the p- and n-transparent metal layers 120 and 122 to electrically connect the nitride semiconductor LED 100 to an external power supply.

Alternatively, the p- and n-transparent electrodes 120 and 122 may be used as p- and n-bonding electrodes in place of the p- and n-bonding electrodes.

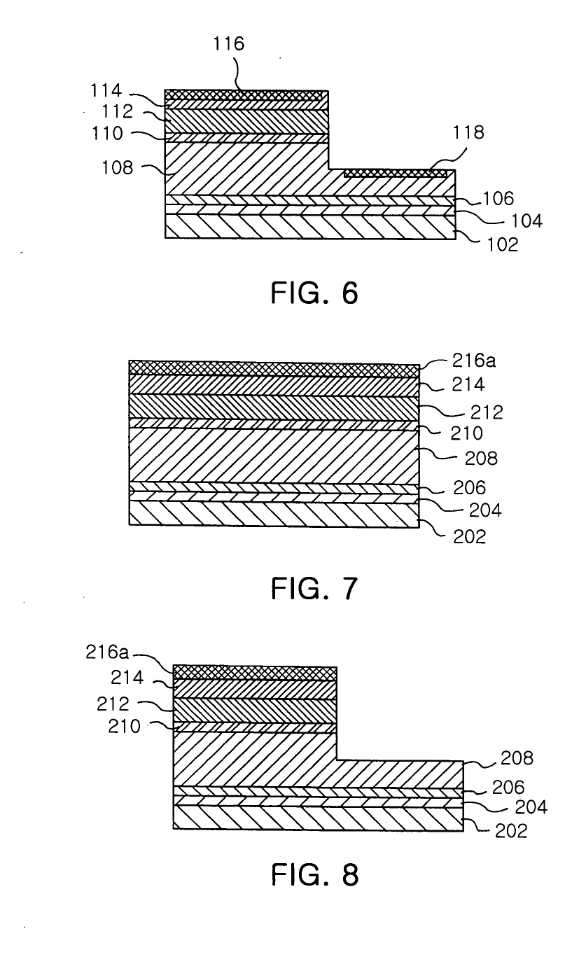

Now a first embodiment of a fabrication method of nitride semiconductors according to the invention will be described with stepwise sectional views of FIGS. 3 to 6 together with FIG. 2.

First, as shown in FIG. 3, a buffer layer 104, an undoped GaN layer 106, an n-doped semiconductor layer 108, an activation layer 110, a p-doped semiconductor layer 112 and a p⁺-doped semiconductor layer 114 are formed in their order on a sapphire substrate 102 via the Metal-Organic Chemical Vapor Deposition (MOCVD) so that the p⁺-doped semiconductor layer 114 is formed at a thickness of 20 Å to 2 μm, and preferably, of 200 to 2000 Å.

Then, as shown in FIG. 4, the entire semiconductor structure is mesa-etched to divide the n-doped semiconductor layer 108 into a first area underlying the active layer 110 and an exposed second area. The etching is not necessarily performed to obtain a stepped geometry from the n-doped semiconductor layer 108 as shown in FIG. 4, but may be carried out to the extent of exposing the second area of the n-doped semiconductor layer 108.

Next, as shown in FIG. 5, a silicone dioxide (SiO₂) layer 130 is deposited on the etched semiconductor structure.

This SiO₂ layer 130 is selectively etched to expose at least a portion of the p⁺-doped semiconductor layer 114 and a portion of the second area of the n-doped semiconductor layer 108.

The SiO₂ layer 130 may be selectively removed via wet etching or dry etching. The wet etching is performed by using Hydrogen Fluoride (HF) or Buffered Oxide Etch (BOE), as a water solution of HF and NH₄F, at a temperature ranging from about 15 to 40° C. for about 10 seconds to 30 minutes. Also, the dry etching is carried out by flowing Carbon Tetraflouride (CF₄) at an RF power ranging from about 100 to 500 W under a pressure of about 10 to 100 mtorr for about 30 seconds to 10 minutes.

Then, ion implantation is carried out in such a fashion that n-dopants are implanted at high concentration into a top region of the p⁺-doped semiconductor layer 114 and the second area of the n-doped semiconductor layer 108 to form first and second n⁺-doped regions 116 and 118, respectively.

The n-dopants are selected from the group consisting of C, Si, Ge, Sn, N, P, As and Sb, and will be fed into a reactor in the form of SiF₄ in case of Si. In the meantime, the n-dopants are ion-implanted at a concentration of about 1E16 atomes/cm² under an acceleration voltage of about 100 eV to 100 keV so that the resultant first and second n⁺-doped regions 116 and 118 preferably have a concentration of about 1E 18 to 1E 20 atoms/cm³ and a thickness of about 10 Å to 1 μm, more preferably, of about 100 to 1000 Å.

As the first n⁺-doped regions 116 is formed at the above thickness, the p⁺-doped semiconductor layer 114 underlying the first n⁺-doped regions 116 has a thickness of about 10 Å to 1 μm, and preferably, of about 100 to 1000 Å.

After the ion implantation carried out as above, a suitable heat treatment such as Rapid Thermal Annealing (RTA) is performed to remove the SiO₂ layer thereby producing a nitride semiconductor structure as shown in FIG. 6, in which the heat treatment is performed at a temperature ranging from about 700 to 1300° C. under nitrogen atmosphere.

Then, p- and n-transparent metal layers 120 and 122 are formed on the first and second n⁺-doped regions 116 and 118 of the resultant nitride semiconductor structure, respectively, so as to produce a nitride semiconductor LED 100 of the invention as shown in FIG. 2.

The p- and n-transparent metal layers 120 and 122 can be made of a material selected from the group consisting of Indium-Tin Oxide (ITO), Cadmium-Tin Oxide (CTO) and Titanium Tungsten Nitride (TiWN) of excellent transparency, and thus improve the luminance of the nitride semiconductor LED 100 of the invention.

In addition, p- and n-bonding electrodes may be further formed on the p- and n-transparent metal layers 120 and 122, respectively, to electrically connect the nitride semiconductor LED 100 with an external power supply.

Alternatively, the p- and n-transparent electrodes 120 and 122 may be used as p- and n-bonding electrodes in place of the p- and n-bonding electrodes.

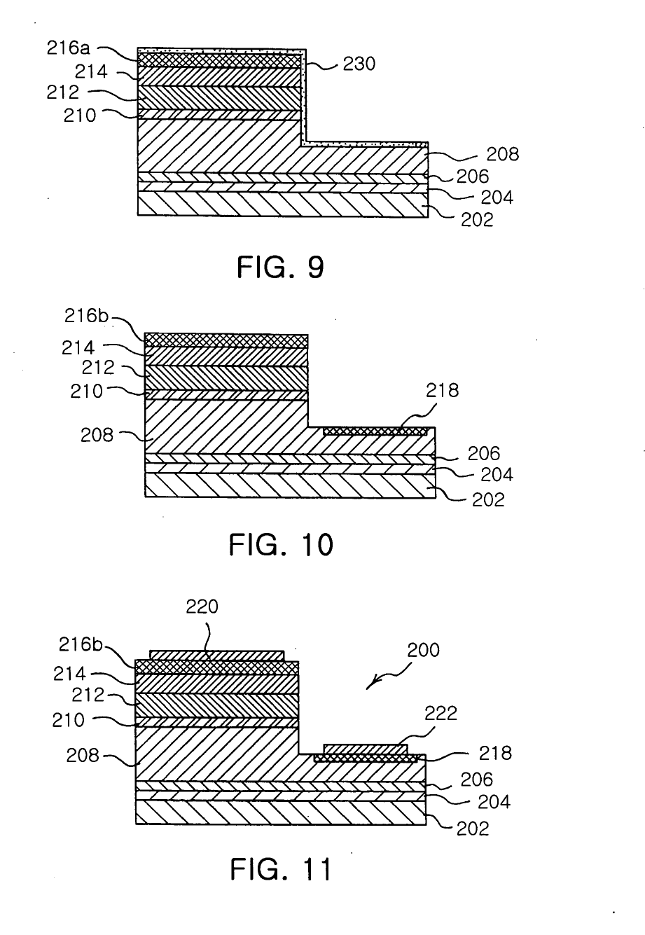

Hereinafter a second embodiment of the fabrication method of nitride semiconductors according to the invention will be described with reference to stepwise sectional views shown in FIGS. 7 to 11, wherein the parts having the same function as those in the first embodiment are designated with the same reference numerals, increased by 100, for the sake of understanding.

First, as shown in FIG. 7, a buffer layer 204, an undoped GaN layer 206, a first n-doped semiconductor layer 208, an active layer 210, a p-doped semiconductor layer 212, a p⁺-doped semiconductor layer 214 and a second n-doped semiconductor layer 216a are formed in their order on a sapphire substrate 202 via the MOCVD so that each of the p⁺-doped semiconductor layer 214 and the second n-doped semiconductor layer 216a has a thickness of about 10 Å to 1 μm, and preferably, of about 100 to 1000 Å.

Then, as shown in FIG. 8, the entire semiconductor structure is mesa-etched to divide the first n-doped semiconductor layer 208 into a first area underlying the active layer 210 and an exposed second area. The etching is not necessarily performed to obtain a stepped geometry from the n-doped semiconductor layer 208, but may be carried out to the extent of exposing the second area of the n-doped semiconductor layer 208.

Next, as shown in FIG. 9, a SiO₂ layer 230 is deposited on the etched semiconductor structure.

Then, the SiO₂ layer 230 is selectively etched to expose at least a portion of the second n-doped semiconductor layer 216a and at least a portion of the second area of the first n-doped semiconductor layer 208.

The SiO₂ layer 230 may be selectively removed via wet etching or dry etching. Detailed procedures of the etchings will not described further since they are carried out under same process conditions as in the first embodiment.

Then, ion implantation is carried out in such a fashion that n-dopants are implanted at high concentration into the second n-doped semiconductor layer 216a and the second area of the first n-doped semiconductor layer 208 to form first and second n⁺-doped regions 216b and 218, respectively.

The n-dopants are selected from the group consisting of C, Si, Ge, Sn, N, P, As and Sb, and will be fed into a reactor in the form of SiF₄ in case of Si. In the meantime, the n-dopants are ion-implanted at a concentration of about 1E16 atomes/cm² under an acceleration voltage of about 100 eV to 100 keV so that the resultant first and second n⁺-doped regions 216b and 218 preferably have a concentration of about 1E 18 to 1E 20 atoms/cm³ and the second n⁺-doped region 218 has a thickness of about 10 Å to 1 μm, more preferably, of about 100 to 1000 Å.

After the ion implantation carried out as above, a suitable heat treatment such as Rapid Thermal Annealing (RTA) is performed to remove the SiO₂ layer thereby producing a nitride semiconductor structure as shown in FIG. 10, in which the heat treatment is performed at a temperature ranging from about 700 to 1300° C. under nitrogen atmosphere.

Then, p- and n-transparent metal layers 220 and 222 are formed on the first and second n⁺-doped regions 216b and 218 of the resultant nitride semiconductor structure, respectively, so as to produce a nitride semiconductor LED 200 of the invention as shown in FIG. 11.

The p- and n-transparent metal layers 220 and 222 can be made of a material selected from the group consisting of Indium-Tin Oxide (ITO), Cadmium-Tin Oxide (CTO) and Titanium Tungsten Nitride (TiWN) of excellent transparency, and thus improve the luminance of the nitride semiconductor LED 200 of the invention.

In addition, p- and n-bonding electrodes may be further formed on the p- and n-transparent metal layers 220 and 222, respectively, to electrically connect the nitride semiconductor LED 200 with an external power supply.

Alternatively, the p-and n-transparent electrodes 220 and 222 may be used as p- and n-bonding electrodes in place of the p- and n-bonding electrodes.

According to the nitride semiconductor LEDs and the fabrication methods thereof of the invention as set forth above, the first n⁺-doped region overlying the p-doped semiconductor layer can form a tunneling junction via reverse bias thereby to ensure an excellent ohmic contact structure while lowering drive voltage.

Furthermore, the improved ohmic contact structure allows the transparent metal layers to be made from one of the group consisting of ITO, CTO and TiWN of excellent transparency thereby improving the luminance of the nitride semiconductor LED of the invention.

While the present invention has been shown and described in connection with the preferred embodiments, it will be apparent to those skilled in the art that modifications and variations can be made without departing from the spirit and scope of the invention as defined by the appended claims.

1. A nitride semiconductor Light Emitting Diode (LED) comprising:
an n-doped semiconductor layer formed on a substrate;
an active layer formed on the n-doped semiconductor layer to expose a partial area of the n-doped semiconductor layer;
a p-doped semiconductor layer formed on the active layer;
a p⁺-doped semiconductor layer formed on the p-doped semiconductor layer;
first and second n⁺-doped regions of a high n-dopant concentration formed on the p⁺-doped semiconductor layer and the exposed area of the n-doped semiconductor layer, respectively; and
p- and n-electrodes formed on the first and second n⁺-doped regions, respectively.

2. The nitride semiconductor LED according to claim 1, wherein the n-dopants are selected from a group consisting of C, Si, Ge, Sn, N, P, As and Sb.

3. The nitride semiconductor LED according to claim 1, wherein the n-dopants have a concentration of 1E18 to 1E20 atoms/cm³.

4. The nitride semiconductor LED according to claim 1, wherein each of the first and second n⁺-doped regions has a thickness of about 10 Å to 1 μm.

5. The nitride semiconductor LED according to claim 1, wherein each of the p- and n-electrodes is made of a material selected from a group consisting of Indium-Tin Oxide (ITO), Cadmium-Tin Oxide (CTO) and Titanium Tungsten Nitride (TiWN).

6. The nitride semiconductor LED according to claim 1, further comprising a first transparent metal layer formed between the n-electrode and the first n⁺-doped region and a second transparent metal layer formed between the p-electrode and the second n⁺-doped region, wherein each of the transparent electrodes is made of a material selected from a group consisting of Indium-Tin Oxide (ITO), Cadmium-Tin Oxide (CTO) and Titanium Tungsten Nitride (TiWN).

7. A fabrication method of nitride semiconductor Light Emitting Diodes (LEDs), the method comprising the following steps of:
forming an n-doped semiconductor layer, an active layer, a p-doped semiconductor layer and a p⁺-doped semiconductor layer in their order on a substrate;
mesa-etching a resultant semiconductor structure to expose a partial area of the n-doped semiconductor layer;
n-doping the p⁺-doped semiconductor layer and the exposed area of the n-doped semiconductor layer at a high concentration to form first and second n⁺-doped regions, respectively; and
forming p- and n-electrodes on the first and second n⁺-doped regions, respectively.

8. The fabrication method of nitride semiconductor LEDs according to claim 7, wherein the n-doping step comprises:
forming a silicon dioxide (SiO₂) layer on the mesa-etched semiconductor structure;
selectively etching the silicon dioxide layer to expose at least a portion of the p⁺-doped semiconductor layer and at least a portion of the exposed area of the n-doped semiconductor layer; and
ion-implanting n-dopants through the etched regions of the silicon dioxide layer into the p⁺-doped semiconductor layer and the exposed area of the n-doped semiconductor layer.

9. The fabrication method of nitride semiconductor LEDs according to claim 7, wherein the n-doping step is carried out by using an element selected from a group consisting of C, Si, Ge, Sn, N, P, As and Sb.

10. The fabrication method of nitride semiconductor LEDs according to claim 7, the n-doping step is carried out at a concentration of 1E18 to 1E20 atoms/cm³.

11. The fabrication method of nitride semiconductor LEDs according to claim 7, wherein each of the first and second n⁺-doped regions has a thickness of about 10 Å to 1 μm.

12. The fabrication method of nitride semiconductor LEDs according to claim 7, wherein each of the p- and n-electrodes is made of a material selected from a group consisting of Indium-Tin Oxide (ITO), Cadmium-Tin Oxide (CTO) and Titanium Tungsten Nitride (TiWN).

13. The fabrication method of nitride semiconductor LEDs according to claim 7, further comprising the step of forming transparent metal layers on the first and second n⁺-doped regions, respectively, before the step of forming p- and n-electrodes,
wherein each of the p- and n-transparent metal layers is made of a material selected from a group consisting of Indium-Tin Oxide (ITO), Cadmium-Tin Oxide (CTO) and Titanium Tungsten Nitride (TiWN).

14. A fabrication method of nitride semiconductor Light Emitting Diodes (LEDs), the method comprising the following steps of:
forming a first n-doped semiconductor layer, an active layer, a p-doped semiconductor layer, a p⁺-doped semiconductor layer and a second n-doped semiconductor layer in their order on a substrate;
mesa-etching a resultant semiconductor structure to expose a partial area of the first n-doped semiconductor layer;
n-doping the second n-doped semiconductor layer to form itself into a first n⁺-doped region and the exposed area of the first n-doped semiconductor layer to form a second n⁺-doped region therein; and
forming p- and n-electrodes on the first and second n⁺-doped regions, respectively.

15. The fabrication method of nitride semiconductor LEDs according to claim 14, wherein the n-doping step comprises:
forming a silicon dioxide (SiO₂) layer on the mesa-etched semiconductor structure;
selectively etching the silicon dioxide layer to expose at least a portion of the second n-doped semiconductor layer and at least a portion of the exposed area of the n-doped semiconductor layer; and
ion-implanting n-dopants through the etched regions of the silicon dioxide layer into the second n-doped semiconductor layer and the exposed area of the first n-doped semiconductor layer.

16. The fabrication method of nitride semiconductor LEDs according to claim 14, wherein the n-doping step is carried out by using an element selected from a group consisting of C, Si, Ge, Sn, N, P, As and Sb.

17. The fabrication method of nitride semiconductor LEDs according to claim 14, wherein the n-doping step is carried out at a concentration of 1E18 to 1E20 atoms/cm³.

18. The fabrication method of nitride semiconductor LEDs according to claim 14, wherein the p⁺-doped semiconductor layer has a thickness of about 10 Å to 1 μm.

19. The fabrication method of nitride semiconductor LEDs according to claim 14, wherein each of the first and second n⁺-doped regions has a thickness of about 10 Å to 1 μm.

20. The fabrication method of nitride semiconductor LEDs according to claim 14, wherein each of the p- and n-electrodes is made of a material selected from a group consisting of Indium-Tin Oxide (ITO), Cadmium-Tin Oxide (CTO) and Titanium Tungsten Nitride (TiWN).

21. The fabrication method of nitride semiconductor LEDs according to claim 14, further comprising the step of forming transparent metal layers on the first and second n⁺-doped regions, respectively, before the step of forming p- and n-electrodes,
wherein each of the p- and n-transparent metal layers is made of a material selected from a group consisting of Indium-Tin Oxide (ITO), Cadmium-Tin Oxide (CTO) and Titanium Tungsten Nitride (TiWN).
